(19) United States
(12) Patent Application Publication
(10) Pub. No.: US 2023/0100076 A1
(43) Pub. Date: Mar. 30, 2023

(54) SUBSTRATE PROCESSING APPARATUS, METHOD OF MANUFACTURING SEMICONDUCTOR DEVICE AND NON-TRANSITORY COMPUTER-READABLE RECORDING MEDIUM

(71) Applicant: Kokusai Electric Corporation, Tokyo (JP)

(72) Inventor: Yusaku OKAJIMA, Toyama (JP)

(21) Appl. No.: 17/943,786

(22) Filed: Sep. 13, 2022

(30) Foreign Application Priority Data
Sep. 27, 2021 (JP) 2021-156334

(51) Int. Cl. H01L 21/67; H01L 21/02; H01L 21/687; H01L 21/677

(52) U.S. Cl. CPC H01L 21/67017; H01L 21/0228; H01L 21/68771; H01L 21/67742

(57) ABSTRACT

According to one aspect of a technique of the present disclosure, there is provided a substrate processing apparatus includes: a substrate support; a process chamber; an upstream side gas guide including: a housing connected to a side portion of the process chamber and extending in a direction away from the process chamber; and partition plates arranged in a vertical direction in the housing; a distributor provided with ejection holes arranged in the vertical direction such that a gas is capable of being supplied through the ejection holes between adjacent partition plates, between the housing and an uppermost partition plate or between the housing and a lowermost partition plate; and a process chamber heater provided between the process chamber and the distributor such that a part thereof is located near an adjacent portion of the housing.

### CROSS REFERENCE TO RELATED APPLICATIONS

This application claims priority under 35 U.S.C. § 119(a)-(d) to Japanese Patent Application No. 2021-156334, filed on Sep. 27, 2021, the entire contents of which are hereby incorporated by reference.

### TECHNICAL FIELD

The present disclosure relates to a substrate processing apparatus, a method of manufacturing a semiconductor device and a non-transitory computer-readable recording medium.

### BACKGROUND

As a substrate processing apparatus used in a manufacturing process of a semiconductor device, for example, a substrate processing apparatus capable of collectively processing (that is, batch-processing) a plurality of substrates may be used.

In recent years, an aspect ratio of a concave structure (or a recess) such as a groove formed on a substrate may increase in accordance with a reduction of a cell area due to a miniaturization of a device such as the semiconductor device, and it is preferable to improve a step coverage performance, for example, when a film is formed on the substrate provided with a deeper concave structure. In order to improve the step coverage performance, it is preferable to sufficiently supply a constituent of the film to a lower portion of the concave structure.

### SUMMARY

According to the present disclosure, there is provided a technique capable of forming a film of a high step coverage performance even with respect to a concave structure of a high aspect ratio.

According to one aspect of the technique of the present disclosure, there is provided a substrate processing apparatus including: a substrate support configured to support a plurality of substrates; a process chamber in which the substrate support is capable of being accommodated; an upstream side gas guide including: a housing connected to a side portion of the process chamber and extending in a direction away from the process chamber; and a plurality of partition plates arranged in a vertical direction in the housing; a distributor provided with a plurality of ejection holes arranged in the vertical direction such that a gas is capable of being supplied through the plurality of ejection holes between adjacent partition plates among the plurality of partition plates, between the housing and an uppermost partition plate among the plurality of partition plates or between the housing and a lowermost partition plate among the plurality of partition plates; and a process chamber heater provided between the process chamber and the distributor such that a part thereof is located in vicinity of an adjacent portion of the housing.

### BRIEF DESCRIPTION OF THE DRAWINGS

FIG. 1 is a diagram schematically illustrating a vertical cross-section of a substrate processing apparatus according to one or more embodiments of the present disclosure.

FIG. 2 is a diagram schematically illustrating a horizontal cross-section of the substrate processing apparatus according to the embodiments of the present disclosure taken along a line α-α′ shown in FIG. 1.

FIG. 3 is a diagram schematically illustrating a relationship among a housing, a heater and a distributor of the substrate processing apparatus according to the embodiments of the present disclosure.

FIG. 4 is a diagram schematically illustrating a substrate support according to the embodiments of the present disclosure.

FIGS. 5A and 5B are diagrams schematically illustrating a gas supplier according to the embodiments of the present disclosure.

FIG. 6 is a diagram schematically illustrating a gas exhauster according to the embodiments of the present disclosure.

FIGS. 7A through 7C are diagrams schematically illustrating gases capable of being used in the embodiments of the present disclosure, respectively.

FIG. 8 is a block diagram schematically illustrating a configuration of a controller and related components of the substrate processing apparatus according to the embodiments of the present disclosure.

FIG. 9 is a flow chart schematically illustrating a process flow of a substrate processing according to the embodiments of the present disclosure.

FIG. 10 is a diagram schematically illustrating a relationship between a temperature and a degree of decomposition of HCDS capable of being used in the embodiments of the present disclosure.

FIGS. 11A through 11C are diagrams schematically illustrating a relationship between a pressure and the degree of decomposition of the HCDS capable of being used in the embodiments of the present disclosure.

FIGS. 12A through 12C are diagrams schematically illustrating exemplary configurations of the distributor according to the embodiments of the present disclosure, respectively.

FIGS. 13A through 13C are diagrams schematically illustrating another exemplary configurations of the distributor according to the embodiments of the present disclosure, respectively.

### DETAILED DESCRIPTION

### Embodiments

Hereinafter, one or more embodiments (also simply referred to as “embodiments”) according to the technique of the present disclosure will be described with reference to the drawings. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### (1) Configuration of Substrate Processing Apparatus

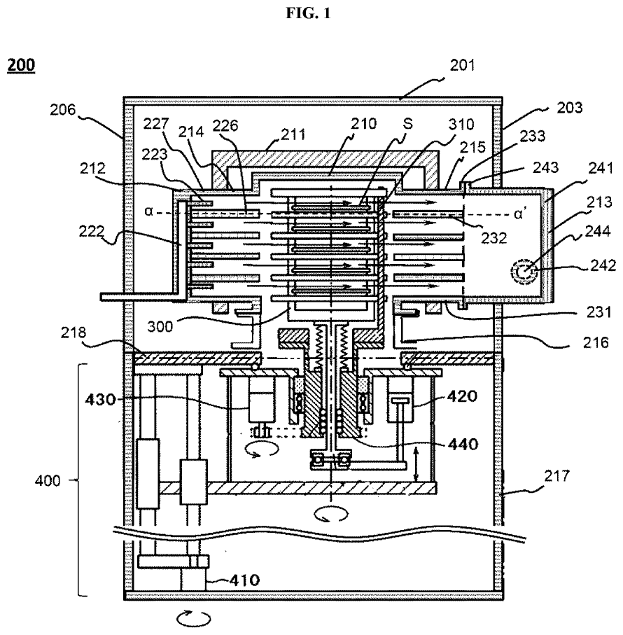

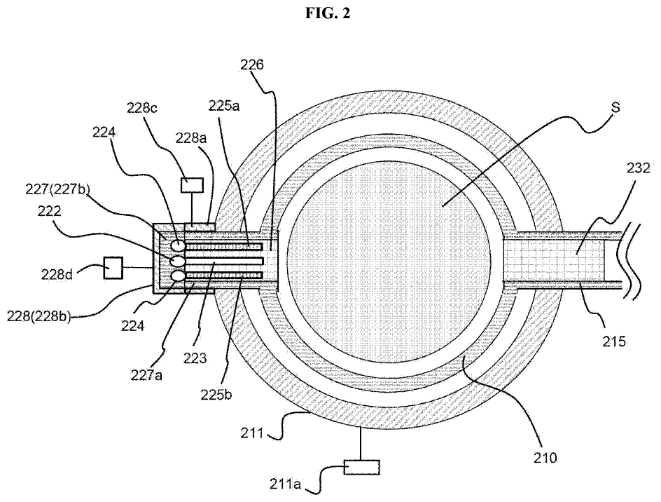

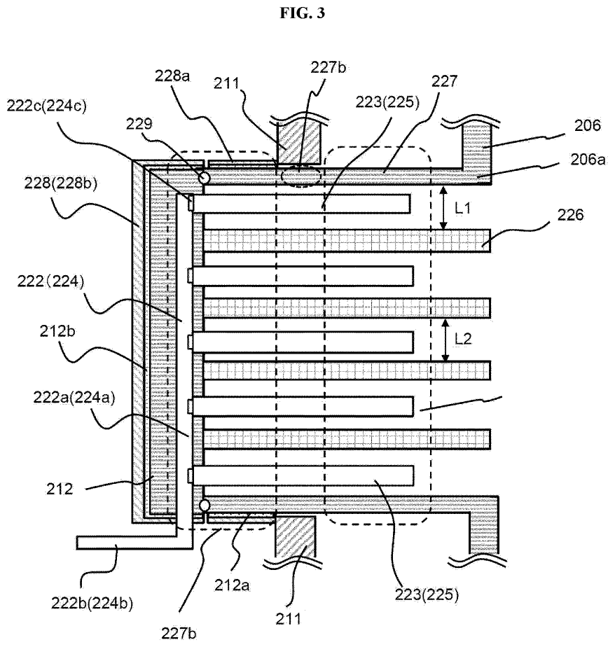

Hereinafter, an outline of a substrate processing apparatus 200 according to the embodiments of the present disclosure will be described with reference to FIGS. 1 through 7C. FIG. 1 is a side sectional view of the substrate processing apparatus 200, and FIG. 2 is a sectional view taken along line a-a′ in FIG. 1. In FIG. 2, for convenience of the following descriptions, a nozzle 223 and a nozzle 225 are additionally illustrated. FIG. 3 is a diagram schematically illustrating a relationship among a housing 227, a heater 211 and distributors 222 and 224. In FIG. 3, for convenience of the following descriptions, the distributor 222 and the nozzle 223 are additionally illustrated, and the distributor 224 and the nozzle 225 are omitted.

Subsequently, the substrate processing apparatus 200 will be described in detail. The substrate processing apparatus 200 includes a housing 201, and the housing 201 includes a reaction tube storage chamber 206 and a transfer chamber 217. The reaction tube storage chamber 206 is arranged on the transfer chamber 217.

In the reaction tube storage chamber 206, a reaction tube 210 of a cylindrical shape extending in a vertical direction, the heater 211 serving as a heating structure (furnace body) installed on an outer periphery of the reaction tube 210, a gas supply structure 212 serving as a part of a gas supplier (which is a gas supply system) and a gas exhaust structure 213 serving as a part of a gas exhauster (which is a gas exhaust system) are provided. In the present specification, the reaction tube 210 may also be referred to as a “process chamber”, and a space in the reaction tube 210 may also be referred to as a “process space”. The reaction tube 210 is configured to be capable of storing a substrate support structure 300 described later.

The heater 211 is provided with a resistance heating heater (not shown) on an inner surface thereof facing the reaction tube 210, and a heat insulator (not shown) is provided so as to surround the heater 211 and the resistance heating heater. Thereby, a portion outside the heater 211 (that is, a portion that does not face the reaction tube 210) is configured to be less affected by a heat. A heater controller 211a is electrically connected to the resistance heating heater of the heater 211. By controlling the heater controller 211a, it is possible to control a turn-on/turn-off (also simply referred to as an “ON/OFF”) of the heater 211 and a heating temperature of the heater 211. The heater 211 is capable of heating a gas described later to a temperature at which the gas is capable of being thermally decomposed. Further, the heater 211 may also be referred to as a “process chamber heater 211” or a “first heater 211”.

In the reaction tube storage chamber 206, the reaction tube 210, an upstream side gas guide 214 and a downstream side gas guide 215 are provided. The gas supplier may further include the upstream side gas guide 214, and the gas exhauster may further include the downstream side gas guide 215.

The gas supply structure 212 is provided at an upstream side in a gas flow direction of the reaction tube 210, and the gas is supplied into the reaction tube 210 through the gas supply structure 212. The gas exhaust structure 213 is provided at a downstream side in the gas flow direction of the reaction tube 210, and the gas in the reaction tube 210 is discharged through the gas exhaust structure 213.

The upstream side gas guide 214 configured to adjust a flow of the gas supplied through the gas supply structure 212 is provided between the reaction tube 210 and the gas supply structure 212. That is, the gas supply structure 212 is provided adjacent to the upstream side gas guide 214. In addition, the downstream side gas guide 215 configured to adjust the flow of the gas discharged from the reaction tube 210 is provided between the reaction tube 210 and the gas exhaust structure 213. A lower end of the reaction tube 210 is supported by a manifold 216.

The reaction tube 210, the upstream side gas guide 214 and the downstream side gas guide 215 are implemented as a continuous structure. For example, each of the reaction tube 210, the upstream side gas guide 214 and the downstream side gas guide 215 is made of a material such as quartz and silicon carbide (SiC). Further, each of the reaction tube 210, the upstream side gas guide 214 and the downstream side gas guide 215 is constituted by a heat permeable structure capable of transmitting the heat radiated from the heater 211. The heat of the heater 211 is capable of heating a plurality of substrates including a substrate S and the gas. Hereafter, the plurality of substrates including the substrate S may also be simply referred to as substrates S.

A housing constituting the gas supply structure 212 is made of a metal, and the housing 227 (which is a part of the upstream side gas guide 214) is made of a material such as quartz. The gas supply structure 212 and the housing 227 are separable from each other. When fixing the gas supply structure 212 and the housing 227, the gas supply structure 212 and the housing 227 are fixed via an O-ring 229. The housing 227 is connected to a connection structure 206a provided on a side wall of the reaction tube 210.

The housing 227 extends in a direction away from the reaction tube 210 when viewed from the reaction tube 210, and is connected to the gas supply structure 212 described later. The heater 211 and the housing 227 are provided adjacent to each other at a portion 227b between the reaction tube 210 and the gas supply structure 212. The portion 227b may also be referred to as an “adjacent portion 227b”.

The gas supply structure 212 is provided inner than the adjacent portion 227b when viewed from the reaction tube 210. The gas supply structure 212 includes the distributor 224 capable of communicating with a gas supply pipe 261 and the distributor 222 capable of communicating with a gas supply pipe 251, which are described later. A plurality of nozzles including the nozzle 223 are provided on a downstream side of the distributor 222, and a plurality of nozzles including the nozzle 225 are provided on a downstream side of the distributor 224. Hereinafter, the plurality of nozzles including the nozzle 223 may also be simply referred to as nozzles 223, and the plurality of nozzles including the nozzle 225 may also be simply referred to as nozzles 225. Each of the nozzles 223 and each of the nozzles 225 are arranged in the vertical direction. In FIG. 1, the distributor 222 and the nozzle 223 are illustrated.

As described later, the distributor 222 may also be referred to as a “source gas distributor” because the distributor 222 is configured to be capable of distributing a source gas. The nozzle 223 may also be referred to as a “source gas supply nozzle” because the source gas is supplied through the nozzle 223.

Further, the distributor 224 may also be referred to as a “reactive gas distributor” because the distributor 224 is configured to be capable of distributing a reactive gas. The nozzle 225 may also be referred to as a “reactive gas supply nozzle” because the reactive gas is supplied through the nozzle 225.

As described later, gases of different types are supplied through the gas supply pipe 251 and the gas supply pipe 261, respectively. As shown in FIG. 2, the nozzle 223 and the nozzle 225 are arranged next to each other in a horizontal direction. According to the present embodiments, for example, the nozzle 223 is arranged on a center of the housing 227 in the horizontal direction, and the nozzles 225 are arranged on both sides of the nozzle 223. The nozzles 225 arranged on both sides of the nozzle 223 may also be referred to as nozzles 225a and 225b, respectively.

As shown in FIG. 3, the distributor 222 is provided with a plurality of ejection holes including an ejection hole 222c. Hereinafter, the plurality of ejection holes including the ejection hole 222c may also be simply referred to as ejection holes 222c. The ejection holes 222c are provided so as not to overlap with one another in the vertical direction. The nozzles 223 are connected to the distributor 222 such that the ejection holes 222c provided at the distributor 222 communicate with inner spaces of the nozzles 223, respectively. The nozzles 223 are provided in the vertical direction, and are arranged between adjacent partition plates (among a plurality of partition plates including a partition plate 226) described later, or between the housing 227 and an uppermost partition plate (among the plurality of partition plates including the partition plate 226), or between the housing 227 and a lowermost partition plate (among the plurality of partition plates including the partition plate 226). Hereinafter, the plurality of partition plates including the partition plate 226 may also be simply referred to as partition plates 226, the uppermost partition plate may also be referred to as an “uppermost partition plate 226”, and the lowermost partition plate may also be referred to as a “lowermost partition plate 226”.

The distributor 222 includes a distribution structure 222a connected to the nozzles 223 and an introduction pipe (also referred to as a “gas introduction pipe”) 222b. The introduction pipe 222b is configured to communicate with the gas supply pipe 251 of a first gas supplier (which is a first gas supply system) 250 described later.

The distribution structure 222a is provided inner than the heater 211 when viewed from the reaction tube 210. Therefore, the distribution structure 222a is arranged at a position where the distribution structure 222a is hardly affected by the heater 211.

An upstream side heater 228 capable of heating at a temperature lower than that of the heater 211 is provided around the gas supply structure 212 and the housing 227. The upstream side heater 228 is constituted by two upstream side heaters 228a and 228b. Specifically, the upstream side heater 228a is provided around a surface of the housing 227 between the gas supply structure 212 and the adjacent portion 227b. Further, the upstream side heater 228b is provided around the gas supply structure 212. The upstream side heater 228 may also be referred to as an “upstream side heating structure” or a “second heater”.

In the present specification, for example, a “low temperature” refers to a temperature at which the gas supplied into the distributor 222 is not re-liquefied and at which the gas is maintained in a low decomposition state.

Similar to the distributor 222, the distributor 224 includes a distribution structure 224a connected to the nozzles 225 and an introduction pipe 224b. The introduction pipe 224b is configured to communicate with the gas supply pipe 261 of a second gas supplier (which is a second gas supply system) 260 described later. The nozzles 225 are connected to the distributor 224 such that a plurality of ejection holes including an ejection hole 224c provided at the distributor 224 communicate with inner spaces of the nozzles 225, respectively. Hereinafter, the plurality of ejection holes including the ejection hole 224c may also be simply referred to as ejection holes 224c. As shown in FIG. 2, a plurality of distributors including the distributor 224 and the nozzles 225, (for example, two distributors including the distributor 224 and two nozzles 225) are illustrated. Hereinafter, the plurality of distributors including the distributor 224 may also be simply referred to as distributors 224. The gas supply pipe 261 is configured to communicate with both of the distributors 224 and the nozzles 225. For example, the nozzles 225 are arranged line-symmetrically with each other with reference to the nozzle 223 interposed therebetween.

By providing different distributors and the nozzles for the gases supplied through the gas supply pipes, the gases supplied through the gas supply pipes described above are not mixed in each distributors. Thereby, it is possible to suppress a generation of particles that may be generated when the gases are mixed in the distributors.

At least a part of the upstream side heater 228a is arranged parallel to an extension direction of the nozzle 223 and an extension direction of the nozzle 225. Further, at least a part of the upstream side heater 228b is provided along an arrangement direction of the distributor 222. With such a configuration, it is possible to maintain the low temperature even in the nozzle such as the nozzle 223 and the nozzle 225 and in the distributor such as the distributor 222.

Heater controllers 228c and 228d are electrically connected to the upstream side heater 228. Specifically, the heater controller 228c is connected to the upstream side heater 228a, and the heater controller 228d is connected to the upstream side heater 228b. By controlling the heater controllers 228c and 228d, it is possible to control a turn-on/turn-off (“ON/OFF”) of the upstream side heater 228 and a heating temperature of the upstream side heater 228. Further, while the present embodiments will be described by way of an example in which the two heater controllers 228c and 228d are provided, the present embodiments are not limited thereto. For example, as long as a desired temperature control is possible, a heater controller or three or more heater controllers may be used instead of the two heater controllers 228c and 228d. Further, the upstream side heater 228 may also be referred to as the “second heater”.

The upstream side heater 228 is a removable configuration, and may be removed from the gas supply structure 212 and the housing 227 in advance when the gas supply structure 212 and the housing 227 are separated from each other. Further, the upstream side heater 228 may be fixed to the gas supply structure 212 or the housing 227, and when the gas supply structure 212 and the housing 227 are separated from each other, the gas supply structure 212 and the housing 227 are separated while the upstream side heater 228 is being fixed to the gas supply structure 212 or the housing 227.

For example, a metal cover 212a made of a metal and serving as a cover may be provided between the upstream side heater 228a and the housing 227. By providing the metal cover 212a, it is possible to efficiently supply the heat generated from the upstream side heater 228a into the housing 227. In particular, since the housing 227 is made of quartz, the heat may leak through the housing 227. However, by providing the metal cover 212a, it is possible to suppress a heat leak through the housing 227. Therefore, it is possible to avoid an excessive heating of the housing 227, and it is also possible to suppress an electrical power supplied to the upstream side heater 228.

A metal cover 212b may be provided between the upstream side heater 228b and the housing constituting the gas supply structure 212. By providing the metal cover 212b, it is possible to efficiently supply the heat generated from the upstream side heater 228b into the distributor. Therefore, it is possible to suppress the electrical power supplied to the upstream side heater 228.

The upstream side gas guide 214 includes the housing 227 and the partition plates 226. A portion of the partition plate 226 serving as a partition structure, which faces the substrate S, extends in the horizontal direction such that a horizontal extending length of the partition plate 226 is at least greater than a diameter of the substrate S. The “horizontal direction” in which the partition plate 226 extends may refer to a direction toward a side wall of the housing 227. The partition plates 226 are arranged in the vertical direction in the housing 227. The partition plate 226 is fixed to the side wall of the housing 227 such that it is possible to prevent the gas from flowing into an adjacent region below or above the partition plate 226. By preventing the gas from flowing into the adjacent region, it is possible to reliably form the flow of the gas described later.

The partition plate 226 is a continuous structure without a hole. The partition plates 226 are provided at positions corresponding to the substrates S, respectively. The nozzles 223 and the nozzles 225 are arranged between adjacent partition plates 226, between the uppermost partition plate 226 and the housing 227 or between the lowermost partition plate 226 and the housing 227. That is, the nozzle 223 and the nozzles 225 are provided at least for each of the partition plates 226. With such a configuration, it is possible to perform a process using a first gas and a second gas in between adjacent partition plates 226, in between the uppermost partition plate 226 and the housing 227 or in between the lowermost partition plate 226 and the housing 227. Therefore, it is possible to uniformize a state of the process between the substrates S.

Further, it is preferable that distances between the partition plates 226 and their corresponding nozzles 223 arranged thereabove are set to be equal to one another. That is, distances between the nozzles 223 and their corresponding partition plates 226 arranged therebelow or distances between the nozzles 223 and the housing 227 are set to be equal to one another. With such a configuration, a distance from a front end (tip) of each of the nozzles 223 to its corresponding one of the partition plates 226 can be set to be constant. Thereby, it is possible to uniformize a degree of decomposition of the gas on each of the substrates S.

The gas ejected through the nozzle 223 and the nozzle 225 is supplied to a surface of the substrate S after the flow of the gas is adjusted by the partition plate 226. Since the partition plate 226 extends in the horizontal direction and is a continuous structure without a hole, a mainstream of the gas is restrained from moving in the vertical direction and is moved in the horizontal direction. Therefore, it is possible to uniformize a pressure loss of the gas reaching each of the substrates S over the vertical direction.

According to the present embodiments, a diameter of each of the ejection holes 222c provided in the distributor 222 is configured to be smaller than a distance between adjacent partition plates 226, a distance between the housing 227 and the uppermost partition plate 226 or a distance between the housing 227 and the lowermost partition plate 226.

The downstream side gas guide 215 is configured such that a ceiling thereof is provided above an uppermost substrate among the substrates S supported by the substrate support structure 300, and a bottom thereof is provided below a lowermost substrate among the substrates S supported by the substrate support structure 300.

The downstream side gas guide 215 includes a housing 231 and a plurality of partition plates including a partition plate 232. Hereinafter, the plurality of partition plates including the partition plate 232 may also be simply referred to as partition plates 232. A portion of the partition plate 232, which faces the substrate S, extends in the horizontal direction such that a horizontal extending length of the partition plate 232 is at least greater than the diameter of the substrate S. The “horizontal direction” in which the partition plate 232 extends may refer to a direction toward a side wall of the housing 231. The partition plates 232 are arranged in the vertical direction in the housing 231. The partition plate 232 is fixed to the side wall of the housing 231 such that it is possible to prevent the gas from flowing into an adjacent region below or above the partition plate 232. By preventing the gas from flowing into the adjacent region, it is possible to reliably form the flow of the gas described later. A flange 233 is provided on a portion of the housing 231 that comes into contact with the gas exhaust structure 213.

The partition plate 232 is a continuous structure without a hole. The partition plates 232 are provided at positions corresponding to the substrates S and corresponding to the partition plates 226, respectively. It is preferable that the partition plate 226 and the partition plate 232 corresponding to the partition plate 226 are provided at the same height. Further, when processing the substrate S, it is preferable that the substrate S, the partition plate 226 corresponding to the substrate S and the partition plate 232 corresponding to the partition plate 226 are provided at the same height. With such a structure, the flow of the gas (supplied through each nozzle) passing over the partition plate 226, the substrate S and the partition plate 232 is formed by the gas supplied through each nozzle, as shown by each arrow in FIG. 1. As described above, the partition plate 232 extends in the horizontal direction and is a continuous structure without a hole. By configuring the partition plate 232 as described above, it is possible to uniformize the pressure loss of the gas ejected (or discharged) through each of the substrates S.

Therefore, the flow of the gas passing through each of the substrates S is formed in the horizontal direction toward the gas exhaust structure 213 while suppressing a flow of the gas in the vertical direction.

By providing the partition plates 226 and the partition plates 232, it is possible to uniformize the pressure loss in the vertical direction at both an upstream and a downstream of each of the substrates S. As a result, it is possible to reliably form the flow of the gas in the horizontal direction while the flow along the vertical direction is suppressed across the partition plate 226, the substrate S and the partition plate 232.

The gas exhaust structure 213 is provided on a downstream side of the downstream side gas guide 215. The gas exhaust structure 213 is constituted mainly by a housing 241 and a gas exhaust pipe connection structure 242. A flange 243 is provided on a portion of the housing 241 adjacent to the downstream side gas guide 215.

The gas exhaust structure 213 communicates with a space of the downstream side gas guide 215. The housing 231 and the housing 241 are continuous in height. That is, a height of a ceiling of the housing 231 is configured to be the same as that of a ceiling of the housing 241, and a height of a bottom of the housing 231 is configured to be the same as that of a bottom of the housing 241.

The gas that has passed through the downstream side gas guide 215 is exhausted through an exhaust hole 244. When the gas is exhausted through the exhaust hole 244, since the gas exhaust structure 213 is not provided with a structure similar to the partition plate described above, the flow of the gas whose direction includes a vertical component is formed toward the exhaust hole 244.

The transfer chamber 217 is installed in a lower portion of the reaction tube 210 via the manifold 216. In the transfer chamber 217, the substrate S may be transferred to (or placed on) the substrate support structure (hereinafter, may also be simply referred to as a “boat”) 300 by a vacuum transfer robot (not shown), or the substrate S may be transferred out of the substrate support structure 300 by the vacuum transfer robot.

In the transfer chamber 217, the substrate support structure 300, a partition plate support 310 (which are collectively referred to as a “substrate retainer” or a “substrate support”) and a vertical driving structure 400 constituting a first driving structure configured to drive the substrate support structure 300 and the partition plate support 310 in the vertical direction and in a rotational direction can be stored. FIG. 1 schematically illustrates a state in which the substrate support structure 300 is elevated by the vertical driving structure 400 and stored in the reaction tube 210.

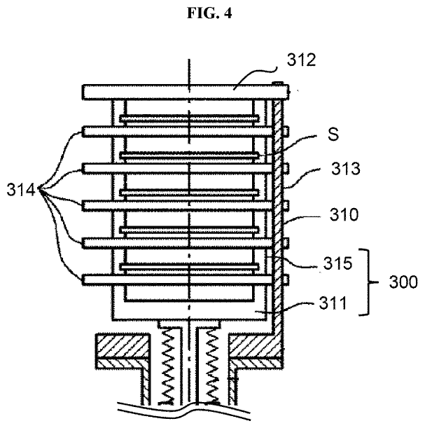

Subsequently, the substrate support will be described in detail with reference to FIGS. 1 and 4. The substrate support is constituted by at least the substrate support structure 300, and is configured to perform a process such as a process of transferring the substrate S by the vacuum transfer robot (not shown) in the transfer chamber 217 via a substrate loading/unloading port (not shown) and a process of loading the transferred substrate S into the reaction tube 210 such that a film-forming step of forming a film on the surface of the substrate S can be performed. For example, the substrate support may further include the partition plate support 310.

In the partition plate support 310, a plurality of partition plates including a partition plate 314 of a disk shape are fixed to a support column 313 supported between a base structure 311 and a top plate 312 at a predetermined pitch. Hereafter, the plurality of partition plates including the partition plate 314 may also be simply referred to as partition plates 314. The substrate support structure 300 (that is, the substrate support) is configured such that a plurality of support rods 315 are supported by the base structure 311 and the substrates S are supported by the plurality of support rods 315 at a predetermined interval.

The substrates S are placed on the substrate support structure 300 at the predetermined interval by the plurality of support rods 315 supported by the base structure 311. The substrates S supported by the support rods 315, respectively, are spaced apart (partitioned) from one another by the partition plates 314 of a disk shape fixed (supported) at the predetermined interval to the support column 313 supported by the partition plate support 310. The partition plates 314 may be provided above each of the substrates S, may be provided below each of the substrates S, or may be provided above and below each of the substrates S.

The predetermined interval between the substrates S placed on the substrate support structure 300 is the same as a vertical interval of the partition plates 314 fixed to the partition plate support 310. Further, a diameter of the partition plate 314 is set to be greater than the diameter of the substrate S.

The boat 300 is configured to support a plurality of substrates (for example, 5 substrates) as the substrates S in a multistage manner in the vertical direction by the plurality of support rods 315. For example, the base structure 311 and the plurality of support rods 315 are made of a material such as quartz and silicon carbide (SiC). Further, the present embodiments will be described by way of an example in which 5 substrates are supported by the boat 300 as the substrates S. However, the present embodiments are not limited thereto. For example, the boat 300 may be configured to be capable of supporting about 5 substrates to 50 substrates as the substrates S. Further, the partition plate 314 fixed to the partition plate support 310 may also be referred to as a “separator”.

The substrate support structure 300 and the partition plate support 310 are driven by the vertical driving structure 400 in the vertical direction between the reaction tube 210 and the transfer chamber 217 and in the rotational direction around a center of the substrate S supported by the substrate support structure 300.

The vertical driving structure 400 constituting the first driving structure includes: as drive sources, a vertical driving motor 410; a rotational driving motor 430; and a boat vertical driving structure 420 provided with a linear actuator (not shown) serving as a substrate support elevator capable of driving the substrate support structure 300 in the vertical direction.

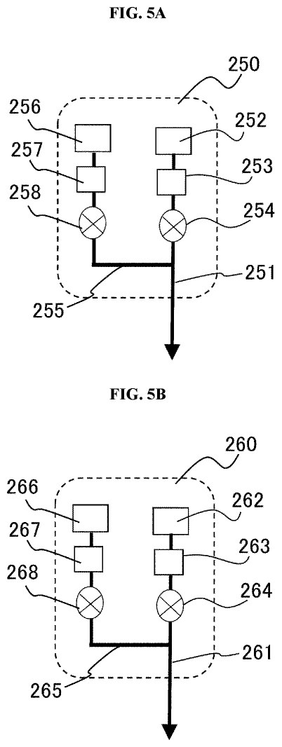

Subsequently, the gas supplier will be described in detail with reference to FIGS. 5A and 5B. As shown in FIG. 5A, a first gas supply source 252, a mass flow controller (MFC) 253 serving as a flow rate controller (a flow rate control structure) and a valve 254 serving as an opening/closing valve are sequentially installed at the gas supply pipe 251 in this order from an upstream side to a downstream side of the gas supply pipe 251.

The first gas supply source 252 is a source of the first gas (also referred to as a “first element-containing gas”) containing a first element. The first gas serves as the source gas, which is one of process gases. According to the present embodiments, the first gas refers to a gas to which at least two silicon (Si) atoms are bonded refers to, for example, a gas containing silicon and chlorine (Cl). For example, the first gas may refer to a source gas containing a silicon—silicon (Si—Si) bond such as disilicon hexachloride (Si2Cl6, hexachlorodisilane, abbreviated as HCDS) gas shown in FIG. 7A. As shown in FIG. 7A, the HCDS gas contains silicon and a chloro group (chloride) in its chemical structural formula (in one molecule).

The Si—Si bond contains enough energy to be decomposed by a collision with a wall constituting a concave structure (or a recess) of the substrate S, which will be described later, in the reaction tube 210. According to the present embodiments, the term “decomposed” means that the Si—Si bond is broken. That is, the Si—Si bond is broken by the collision with the wall.

The first gas supplier 250 is constituted mainly by the gas supply pipe 251, the MFC 253 and the valve 254. The first gas supplier 250 may also be referred to as a silicon-containing gas supplier (which is a silicon-containing gas supply structure or a silicon-containing gas supply system). The gas supply pipe 251 is connected to the introduction pipe 222b of the distributor 222.

A gas supply pipe 255 is connected to a downstream side of the valve 254 in the gas supply pipe 251. An inert gas supply source 256, an MFC 257 and a valve 258 serving as an opening/closing valve are sequentially installed at the gas supply pipe 255 in this order from an upstream side to a downstream side of the gas supply pipe 255. An inert gas (for example, nitrogen (N2) gas) is supplied from the inert gas supply source 256.

A first inert gas supplier (which is a first inert gas supply system) is constituted mainly by the gas supply pipe 255, the MFC 257 and the valve 258. The inert gas supplied from the inert gas supply source 256 acts as a purge gas for purging the gas remaining in the reaction tube 210 when a substrate processing described later is performed. The first gas supplier 250 may further include the first inert gas supplier.

As shown in FIG. 5B, a second gas supply source 262, a mass flow controller (MFC) 263 serving as a flow rate controller (a flow rate control structure) and a valve 264 serving as an opening/closing valve are sequentially installed at the gas supply pipe 261 in this order from an upstream side to a downstream side of the gas supply pipe 261. The gas supply pipe 261 is connected to the introduction pipe 224b of the distributor 224.

The second gas supply source 262 is a source of the second gas (also referred to as a “second element-containing gas”) containing a second element. The second element-containing gas is one of the process gases. Further, the second element-containing gas acts as the reactive gas or a modification gas.

According to the present embodiments, the second element-containing gas contains the second element different from the first element. As the second element, for example, oxygen (O), nitrogen (N) or carbon (C) may be used. According to the present embodiments, for example, a nitrogen-containing gas may be used as the second element-containing gas. Specifically, as the nitrogen-containing gas, a hydrogen nitride-based gas containing a nitrogen—hydrogen (N—H) bond such as ammonia (NH3), diazene (N2H2) gas, hydrazine (N2H4) gas and N3H8 gas.

The second gas supplier 260 is constituted mainly by the gas supply pipe 261, the MFC 263 and the valve 264.

A gas supply pipe 265 is connected to a downstream side of the valve 264 in the gas supply pipe 261. An inert gas supply source 266, an MFC 267 and a valve 268 serving as an opening/closing valve are sequentially installed at the gas supply pipe 265 in this order from an upstream side to a downstream side of the gas supply pipe 265. The inert gas (for example, nitrogen (N2) gas) is supplied from the inert gas supply source 266.

A second inert gas supplier (which is a second inert gas supply system) is constituted mainly by the gas supply pipe 265, the MFC 267 and the valve 268. The inert gas supplied from the inert gas supply source 266 acts as the purge gas for purging the gas remaining in the reaction tube 210 when the substrate processing described later is performed. The second gas supplier 260 may further include the second inert gas supplier.

It is preferable that no obstruction structure obstructing the flow of the gas is provided among the nozzle 223, the nozzles 225 and the substrate S. In particular, no obstruction structure is arranged between the nozzle 223 through which the gas containing the silicon—silicon bond is supplied and the substrate S.

For example, when the obstruction structure obstructing the flow of the gas is provided, the gas may collide with the obstruction structure and then a partial pressure of the gas may increase. Then, a decomposition of the gas may be excessively promoted. In such a case, an amount of the gas consumption may increase, and an amount of the gas in an undecomposed state supplied to the concave structure may decrease. As a result, it may not be possible to obtain a desired step coverage.

Therefore, it is preferable that no obstruction structure is provided for the purpose of suppressing a pressure (that is, the partial pressure) so as not to increase to a pressure at which the decomposition of the gas is promoted. Although it is described that “no obstruction structure is provided” in the present embodiments, some obstruction structures may be provided as long as the partial pressure is not elevated to the pressure at which the decomposition of the gas is promoted.

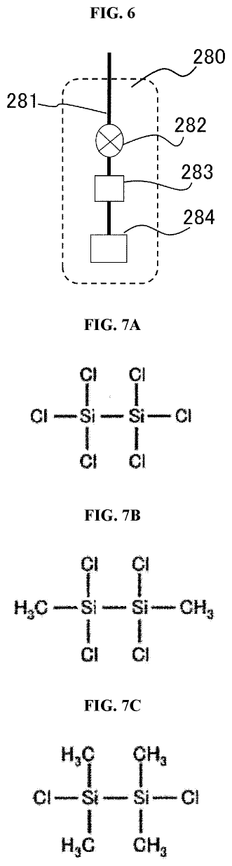

Subsequently, an exhauster (which is an exhaust system) 280 will be described with reference to FIG. 6. The exhauster 280 configured to exhaust an inner atmosphere of the reaction tube 210 includes an exhaust pipe 281 that communicates with the reaction tube 210, and is connected to the housing 241 via the gas exhaust pipe connection structure 242.

As shown in FIG. 6, a vacuum pump 284 serving as a vacuum exhaust apparatus is connected to the exhaust pipe 281 via a valve 282 serving as an opening/closing valve, an APC (Automatic Pressure Controller) valve 283 serving as a pressure regulator (which is a pressure adjusting structure). Thereby, the reaction tube 210 is vacuum-exhausted such that an inner pressure of the reaction tube 210 reaches and is maintained at a predetermined pressure (vacuum degree). The exhauster 280 may also be referred to as a process chamber exhauster (which is a process chamber exhaust system).

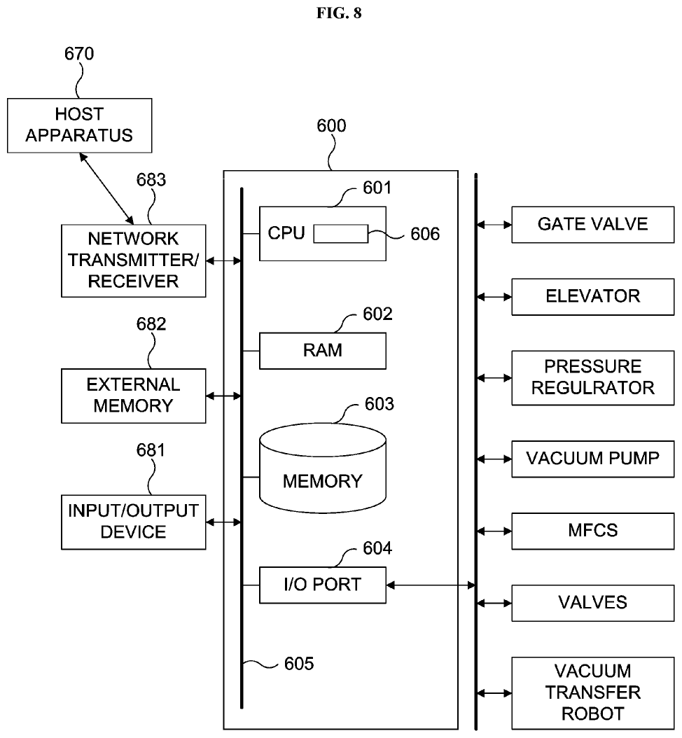

Subsequently, a controller 600 will be described with reference to FIG. 8. The substrate processing apparatus 200 includes the controller 600 configured to control operations of components constituting the substrate processing apparatus 200.

FIG. 8 is a diagram schematically illustrating a configuration of the controller 600. The controller 600 serving as a control structure (control apparatus) may be embodied by a computer including a CPU (Central Processing Unit) 601, a RAM (Random Access Memory) 602, a memory 603 serving as a memory structure and an I/O port (input/output port) 604. The RAM 602, the memory 603 and the I/O port 604 may exchange data with the CPU 601 via an internal bus 605. The transmission/reception of the data in the substrate processing apparatus 200 may be performed by an instruction from a transmission/reception instruction controller 606, which is also one of functions of the CPU 601.

A network transmitter/receiver 683 connected to a host apparatus 670 via a network is provided at the controller 600. For example, the network transmitter/receiver 683 is capable of receiving data such as information regarding a processing history and a processing schedule of the substrate S stored in a pod (not shown) from the host apparatus 670.

For example, the memory 603 may be embodied by a component such as a flash memory and a HDD (Hard Disk Drive). For example, a control program for controlling the operations of the substrate processing apparatus 200 or a process recipe in which information such as sequences and conditions of the substrate processing is stored may be readably stored in the memory 603.

The process recipe is obtained by combining steps of the substrate processing described later, and acts as a program that is executed by the controller 600 to obtain a predetermined result by performing the steps of the substrate processing described later. Hereinafter, the process recipe and the control program may be collectively or individually referred to simply as a “program”. Thus, in the present specification, the term “program” may refer to the process recipe alone, may refer to the control program alone, or may refer to both of the process recipe and the control program. The RAM 602 serves as a memory area (work area) in which the program or the data read by the CPU 601 are temporarily stored.

The I/O port 604 is electrically connected to the components of the substrate processing apparatus 200 described above. The CPU 601 is configured to read and execute the control program from the memory 603, and is configured to read the process recipe from the memory 603 in accordance with an instruction such as an operation command inputted from an input/output device 681. The CPU 601 is configured to be capable of controlling the substrate processing apparatus 200 in accordance with contents of the process recipe read from the input/output device 681.

The CPU 601 includes the transmission/reception instruction controller 606. For example, the controller 600 according to the present embodiments may be embodied by preparing an external memory 682 (for example, a magnetic disk such as a hard disk, an optical disk such as a DVD, a magneto-optical disk such as an MO, a semiconductor memory such as a USB memory) storing the program described above and by installing the program onto the computer by using the external memory 682. Further, a method of providing the program to the computer is not limited to the external memory 682. For example, the program may be directly provided to the computer by a communication interface such as the Internet and a dedicated line instead of the external memory 682. Further, the memory 603 and the external memory 682 may be embodied by a non-transitory computer-readable recording medium. Hereinafter, the memory 603 and the external memory 682 may be collectively or individually referred to as a “recording medium”. In the present specification, the term “recording medium” may refer to the memory 603 alone, may refer to the external memory 682 alone, or may refer to both of the memory 603 and the external memory 682.

Hereinafter, as a part of a manufacturing process of a semiconductor device, the substrate processing will be described by way of an example in which a film-forming process of forming the film on the substrate S is performed by using the substrate processing apparatus 200 described above. In the following description, the controller 600 controls the operations of the components constituting the substrate processing apparatus 200.

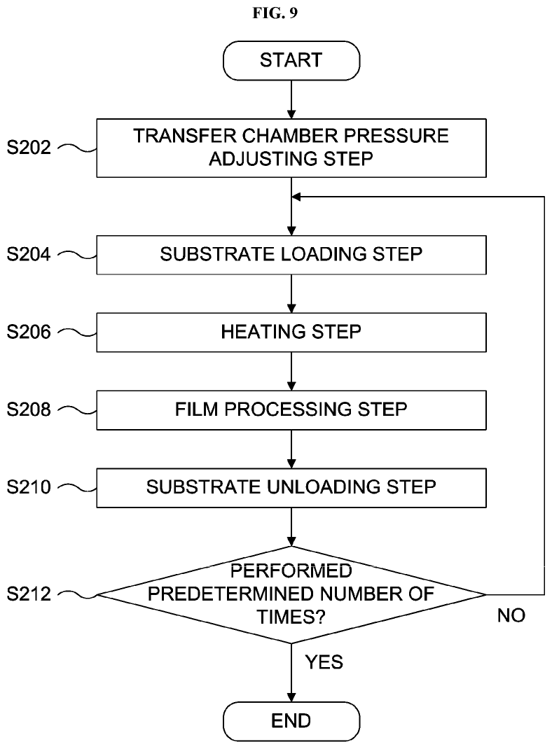

For example, the film-forming process of forming the film on the substrate S by alternately supplying the first gas and the second gas will be described with reference to FIG. 9.

### Transfer Chamber Pressure Adjusting Step S202

A transfer chamber pressure adjusting step S202 will be described. In the step S202, an inner pressure of the transfer chamber 217 is set to the same level as that of a vacuum transfer chamber (not shown) provided adjacent to the transfer chamber 217. Specifically, by operating an exhauster (which is an exhaust system) (not shown) connected to the transfer chamber 217, an inner atmosphere of the transfer chamber 217 is exhausted such that the inner pressure of the transfer chamber 217 reaches and is maintained at a vacuum level.

Further, the upstream side heater 228 may be operated in parallel with the step S202. Specifically, each of the upstream side heater 228a and the upstream side heater 228b may be operated. When the upstream side heater 228 is operated, the upstream side heater 228 is operated at least until a film processing step S208 described later is completed.

### Substrate Loading Step S204

Subsequently, a substrate loading step S204 will be described. When the inner pressure of the transfer chamber 217 reaches the vacuum level, a transfer of the substrate S is started. When the substrate S reaches the vacuum transfer chamber (not shown), a gate valve (not shown) provided adjacent to the substrate loading/unloading port (not shown) is opened. Then, the substrate S is loaded (transferred) from the vacuum transfer chamber (not shown) adjacent to the transfer chamber 217 into the transfer chamber 217.

When the substrate S is loaded, the substrate support structure 300 stands by in the transfer chamber 217, and the substrate S is transferred to the substrate support structure 300. When a predetermined number of substrates S are transferred to the substrate support structure 300, the vacuum transfer robot (not shown) is retracted to a housing (not shown) and the substrate support structure 300 is elevated by the vertical driving structure 400 to move the substrates S into the reaction tube 210.

When moving the substrate S into the reaction tube 210, the substrate S is position-determined such that a height of its surface is aligned with heights of the partition plate 226 and the partition plate 232.

### Heating Step S206

Subsequently, a heating step S206 will be described. When the substrate S is loaded into the reaction tube 210, the inner pressure of the reaction tube 210 is controlled (or adjusted) to be a predetermined pressure, and a surface temperature of the substrate S is controlled to be a predetermined temperature by controlling the heater 211. The temperature (that is, the surface temperature) is a temperature within a high temperature range described later. For example, the substrate S is heated to the temperature within a range of 400° C. or higher and 800° C. or lower, preferably 500° C. or higher and 700° C. or lower. For example, the pressure (that is, the inner pressure of the reaction tube 210) may be a pressure within a range of 50 Pa to 5,000 Pa. In the heating step S206, when the upstream side heater 228 is operated, the gas passing through an inner portion of the distributor 222 is controlled to be heated to a temperature in a low decomposition temperature range or an undecomposition temperature range which will be described later such that the gas is not re-liquefied. For example, the gas is heated to about 300° C.

### Film Processing Step S208

Subsequently, the film processing step S208 will be described. After the heating step S206, the film processing step S208 is performed. In the film processing step S208, in accordance with the process recipe, the first gas supplier 250 is controlled to supply the first gas into the reaction tube 210, and the exhauster 280 is controlled to exhaust the process gases such as the first gas from the reaction tube 210. Further, in the film processing step S208, the second gas supplier 260 is controlled such that the second gas exists in the process space simultaneously with the first gas so as to perform a CVD (chemical vapor deposition) process, or such that the first gas and the second gas are alternately supplied into the reaction tube 210 so as to perform an alternate supply process. Thereby, the film is formed. Further, when the second gas in a plasma state is used, the second gas may be converted into the plasma state by using a plasma generator (not shown).

The following method may be used as the alternate supply process serving as a specific example of a film processing method. For example, a first step of supplying the first gas into the reaction tube 210, a second step of supplying the second gas into the reaction tube 210 and a purge step of supplying the inert gas into the reaction tube 210 and exhausting the inner atmosphere of the reaction tube 210 between the first step and the second step may be performed. That is, a desired film is formed by performing the alternate supply process in which a combination of the first step, the purge step and the second step is performed a plurality number of times.

When the gas is supplied, the flow of the gas is formed at the upstream side gas guide 214, a space on the substrate S and the downstream side gas guide 215. In the film processing step S208, since the gas is supplied to each of the substrates S without the pressure loss on each of the substrates S, it is possible to uniformly process the substrates S.

### Substrate Unloading Step S210

Subsequently, a substrate unloading step S210 will be described. In the substrate unloading step S210, the substrate S processed as described above is transferred (unloaded) out of the transfer chamber 217 in the order reverse to that of the substrate loading step S204 described above.

### Determination Step S212

Subsequently, a determination step S212 will be described. In the determination step S212, it is determined whether or not a processing described above (that is, the step S204 through 5210) has been performed a predetermined number of times. When it is determined that the processing has not been performed the predetermined number of times, the substrate loading step S204 is performed again to process a subsequent substrate S to be processed. When it is determined that the processing has been performed the predetermined number of times, the substrate processing is terminated.

While the present embodiments are described by way of an example in which the flow of the gas in the horizontal direction is formed, the present embodiments are not limited thereto. For example, it would suffice if a main flow of the gas is formed generally in the horizontal direction. Further, a flow of the gas diffused in the vertical direction may be formed as long as it does not affect a uniform processing of the substrates S.

Further, in the above, various expressions such as “the same”, “similar” and the like are used. However, it goes without saying that the expressions described above may mean “substantially the same”.

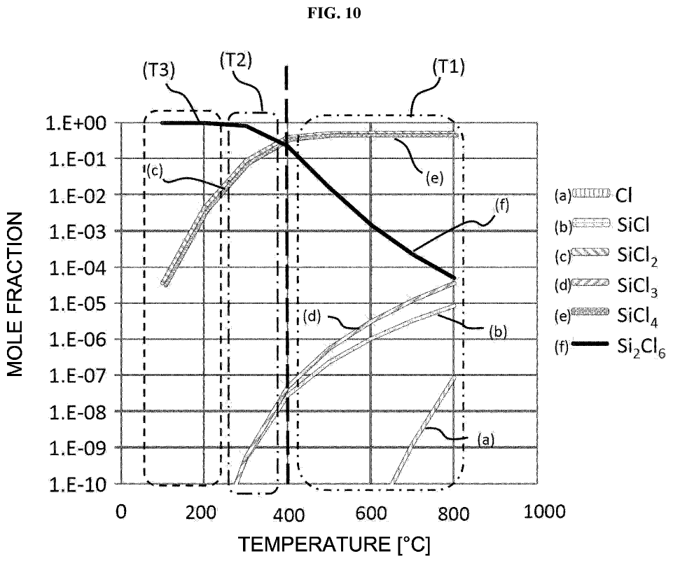

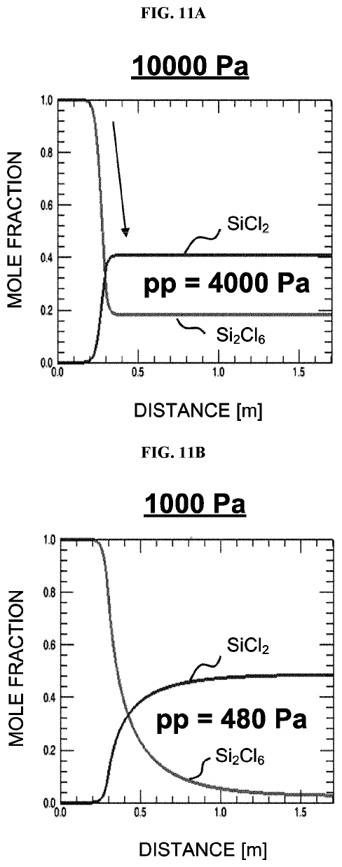

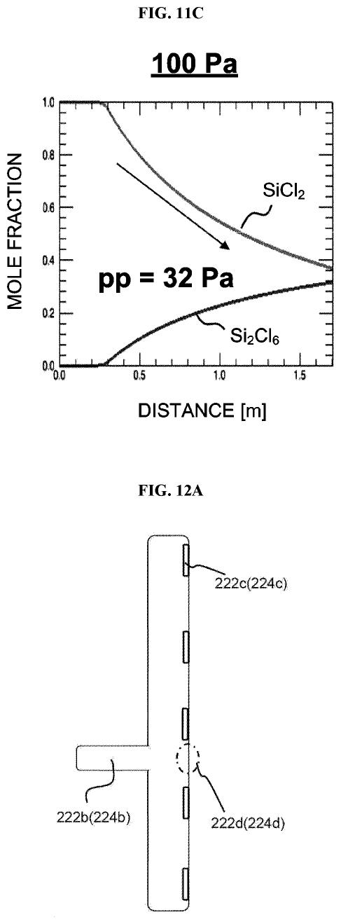

Subsequently, a state of the gas in the film processing step S208 will be described. In the film processing step S208, for example, the first gas is supplied to the reaction tube 210. Properties of the first gas will be described with reference to FIGS. 10 and 11A through 11C using the HCDS (Si2Cl6) gas as an example.

FIG. 10 is a diagram schematically illustrating a relationship between a temperature and a degree of decomposition of the HCDS. FIGS. 11A through 11C are diagrams schematically illustrating a relationship between a pressure and the degree of decomposition of the HCDS. In FIG. 10, a vertical axis indicates a mole fraction and a horizontal axis indicates the temperature. The HCDS is mainly decomposed into SiCl4 and SiCl2. In FIG. 10, “(a)” indicates the chlorine (Cl) after the HCDS is decomposed, “(b)” indicates SiCl after the HCDS is decomposed, “(c)” indicates the SiCl2 after the HCDS is decomposed, “(d)” indicates SiCl3 after the HCDS is decomposed, “(e)” indicates the SiCl4 after the HCDS is decomposed, and “(f)” indicates the HCDS (Si2Cl6). As can be seen from FIG. 10, a ratio of the SiCl2 and a ratio of the SiCl4 gradually increase from about 100° C., and are respectively maintained at a constant ratio when the temperature exceeds 400° C. On the other hand, HCDS (Si2Cl6) is gradually decomposed when the temperature exceeds about 300° C., and rapidly decomposed when the temperature exceeds 400° C. According to the present embodiments, a region (“T1”) which is a temperature range in which the decomposition is promoted may also be referred to as a “high decomposition temperature range”, a region (“T2”) which is a temperature range in which the decomposition is promoted but the HCDS gas is maintained in the low decomposition state may also be referred to as the “low decomposition temperature range”, and a region (“T3”) which is a temperature range in which the HCDS gas is hardly decomposed may also be referred to as an “undecomposed temperature range”.

In FIGS. 11A through 11C, three graphs for each measured pressure are illustrated. In each graph, a vertical axis indicates the mole fraction of the HCDS, and a horizontal axis indicates a traveling distance (or a moving distance) of the HCDS. In FIG. 11A, a case when the pressure of 10,000 Pa is measured is illustrated. In FIG. 11B, a case when the pressure of 1,000 Pa is measured is illustrated. In FIG. 11C, a case when the pressure of 100 Pa is measured is illustrated. Further, in each case, the measured temperature is set to be the same. Further, in each case, it is assumed that the HCDS is decomposed as the mole fraction of the HCDS (Si2Cl6) decreases and the mole fraction of the SiCl2 increases.

Comparing the three graphs, it can be seen that the higher the pressure, the higher the mole fraction of the SiCl2 at the shortest distance. That is, it can be seen that the higher the pressure, the faster the decomposition of the HCDS.

By the way, according to the present embodiments, it is preferable to transport the gas in the undecomposed state onto the substrate S in order to allow a constituent of the gas to reach a lower portion of the concave structure. The gas in the undecomposed state collides with a side wall of the concave structure and then is decomposed, and the decomposed constituent is attached to a bottom of the concave structure. As a result, it is possible to form a film of a high step coverage even with respect to the concave structure of a high aspect ratio.

In order to form the film of the high step coverage, according to the present embodiments, the distributor 222 is provided outside a location where the heater 211 and the housing 227 are adjacent to each other. A temperature of the distributor 222 is maintained in the low decomposition temperature range or the undecomposition temperature range. Thereby, it is possible to transfer (or supply) the gas in a temperature range in which the decomposition is not promoted.

Further, the distributor 222 is configured such that an inner pressure of the distributor 222 is set to be a high pressure at which the decomposition is not promoted. In order to obtain the high pressure, the diameter of each of the ejection holes 222c of the distributor 222 is configured to be smaller than the distance L1 between the housing 227 and the uppermost partition plate 226 (or between the housing 227 and the lowermost partition plate 226) or the distance L2 between adjacent partition plates 226. With such a configuration, it is possible to set the inner pressure of the distributor 222 to such a pressure at which the decomposition is not promoted. Further, it is preferable that the distance L1 and the distance L2 are the same distance in order to uniformize the state of the gas.

Further, the diameter of each of the ejection holes 222c may be gradually increased as each of the ejection holes 222c is spaced apart from the introduction pipe 222b. With such a configuration, the inner pressure of the distributor 222 does not increase even at a front end (tip) of the distribution structure 222a. Therefore, even at the front end of the distribution structure 222a, it is possible to set the inner pressure of the distributor 222 to such a pressure at which the decomposition is not promoted.

Subsequently, as a first comparative example, a case where the distributor such as the distributor 222 is provided inside the adjacent portion 227b where the heater 211 and the housing 227 are provided adjacent to each other (that is, the distributor is provided between the heater 211 and the reaction tube 210) will be described. In such a case, the gas supplied to the distributor fills in the distributor, but a phenomenon in which a temperature of an upper portion of the distributor is different from that of a lower portion of the distributor may occur.

The reason for such a phenomenon is that the traveling distance of the gas is different. Specifically, when the gas supply pipe is connected below the distributor, the traveling distance of the gas ejected from the upper portion of the distributor is longer than the traveling distance of the gas ejected from the lower portion of the distributor. Then, the gas ejected from the upper portion of the distributor is affected by the heater 211 for a long time. As a result, the temperature of the gas ejected from the upper portion of the distributor becomes high and the decomposition of the gas is promoted. On the other hand, since the traveling distance of the gas ejected from the lower portion of the distributor is short, and the gas ejected from the lower portion of the distributor is less affected by the heater 211. As a result, the decomposition of the gas is not promoted as compared with that of the gas ejected from the upper portion of the distributor.

As described above, the decomposition of the gas becomes different at the upper portion and the lower portion of the distributor. Thereby, the state of the gas supplied to the substrate S becomes different at the upper portion and the lower portion of the distributor. In such a case, since a processing state becomes different between the substrates S, a product yield may decrease.

Further, as a second comparative example, without using the distributor, nozzles or the like through which the gas is directly supplied between the partition plates are provided, and an MFC or a valve for controlling a supply of the gas is provided for each nozzle. However, it is not realistic since the number of components increases significantly, which leads to a significant cost increase. Furthermore, considering that many MFCs and valves will be arranged according to the second comparative example, it is difficult to secure a region large enough for accommodating those many components in the vicinity of the reaction tube storage chamber 206 from a viewpoint of securing a maintenance region and a degree of freedom in design. Therefore, the components according to the second comparative example may have no choice but to be provided in a remote location.

In the remote location from the reaction tube storage chamber 206, since the pressure loss to the nozzle is great, it is not possible to secure a sufficient flow velocity of the gas. Therefore, the gas is heated by the heater 211 to the temperature at which the decomposition is promoted before the gas reaches the substrate S. As a result, it is not possible to supply the gas in the undecomposed state onto the substrate S. In such a case, the film is deposited on an upper portion or on a surface of the concave structure. Thereby, it is difficult to form the film of the high step coverage.

On the other hand, according to the present embodiments, the distributor 222 is provided outside the portion where the heater 211 and the housing 227 are provided adjacent to each other. Therefore, it is possible to supply the gas to the housing 227 in a state where the decomposition of the gas is not promoted.

Further, the inner pressure of the distributor 222 is set to a pressure at which the low decomposition state of the gas can be maintained, and is set to be higher than an inner pressure of the upstream side gas guide 214. Thereby, it is possible to suppress the promotion of the decomposition due to an increase in the pressure throughout the range from the distributor 222 to the upstream side gas guide 214. Therefore, it is possible to supply the gas in the low decomposition state to the substrate S, and as a result, it is possible to form the film of the high step coverage.

Further, when supplying the gas, the distributor 222 may be heated by the second heater 228. In such a case, it is preferable that the temperature of the gas supplied to the distributor 222 is adjusted to a temperature at which the low decomposition state of the gas can be maintained such that the gas can be decomposed in the concave structure of the substrate S. For example, the distributor 222 may be heated to a temperature in the low decomposition temperature range of the region T2 shown in FIG. 10. That is, the distributor 222 may be heated to a temperature lower than that of the first heater 211.

Although the distributor 222 is mainly described as an example in the present embodiments, the same also applies to the distributor 224. Therefore, the description thereof will be omitted.

### Modified Examples of Distributor

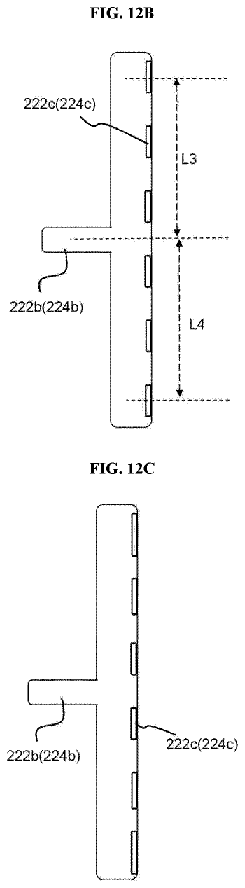

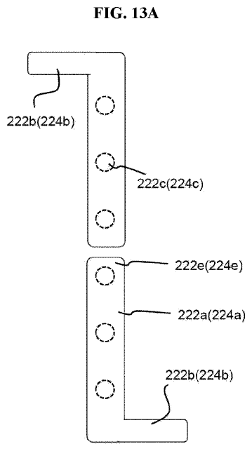

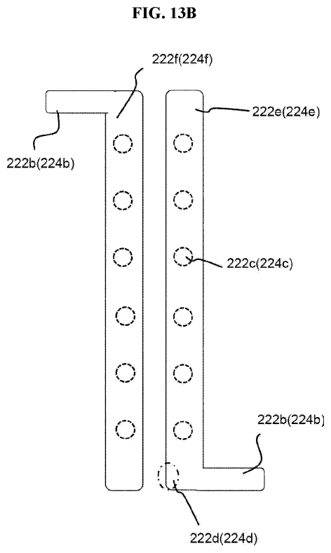

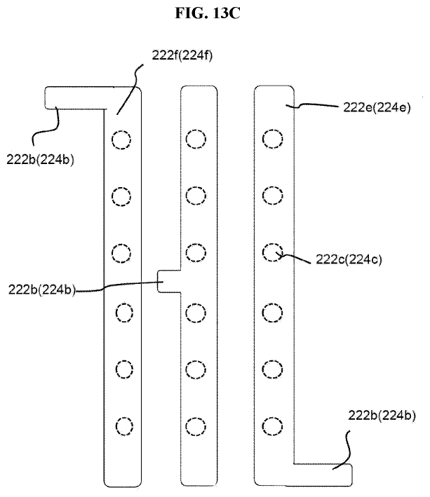

Subsequently, modified examples of the distributor 222 will be described with reference to FIGS. 12A through 12C and 13A through 13C. FIGS. 12A through 12C are diagrams of exemplary configurations of the distributor 222 when viewed from side portions thereof. FIGS. 13A through 13C are diagrams of another exemplary configurations of the distributor 222 when viewed from a direction a shown in FIG. 1.

Referring to FIG. 12A, the introduction pipe 222b is connected to the distribution structure 222a between an uppermost ejection hole among the ejection holes 222c and a lowermost ejection hole among the ejection holes 222c in the vertical direction. Hereinafter, the uppermost ejection hole among the ejection holes 222c may also be simply referred to as an “uppermost ejection hole 222c”, and the lowermost ejection hole among the ejection holes 222c may also be simply referred to as a “lowermost ejection hole 222c”. With such a configuration, it is possible to reduce a pressure difference in the distribution structure 222a, in particular, a pressure difference between a central portion and a front end portion of the distribution structure 222a. Therefore, it is possible to improve a processing uniformity between the substrates S.

Further, it is preferable that a release port of the introduction pipe 222b does not face the ejection holes 222c. That is, it is preferable that the gas ejected through the ejection holes 222c collides with a collision portion 222d. This is because, when the release port of the introduction pipe 222b faces an ejection hole among the ejection holes 222c, an amount of the gas ejected through the ejection hole facing the release port is greater than that of the gas ejected through another ejection hole among the ejection holes 222c. Therefore, as shown in FIG. 12A, it is preferable that the release port of the introduction pipe 222b does not face the ejection holes 222c. For example, the release port of the introduction pipe 222b faces the collision portion 222d which is a wall constituting the distribution structure 222a.

Referring to FIG. 12B, the introduction pipe 222b is connected to the distribution structure 222a between the uppermost ejection hole 222c and the lowermost ejection hole 222c in the vertical direction. Further, the introduction pipe 222b is connected to the distribution structure 222a such that a distance from the introduction pipe 222b to a first ejection hole among the ejection holes 222c and a distance from the introduction pipe 222b to a second ejection hole (which is located vertically opposite to the first ejection hole with respect to the introduction pipe 222b) among the ejection holes 222c are set to be equal to each other in the vertical direction. For example, a distance L3 from the introduction pipe 222b to the uppermost ejection hole 222c and a distance L4 from the introduction pipe 222b to the lowermost ejection hole 222c are set to be equal to each other. With such a configuration, it is possible to reduce the pressure difference in the distribution structure 222a, in particular, the pressure difference between the central portion and the front end portion of the distribution structure 222a. Therefore, by reducing the difference in the degree of decomposition of the gas as described above, it is possible to improve the processing uniformity between the substrates S.

Referring to FIG. 12C, the introduction pipe 222b is connected to the distribution structure 222a between the uppermost ejection hole 222c and the lowermost ejection hole 222c in the vertical direction. Further, the ejection holes 222c are configured such that the diameter of each of the ejection holes 222c increases as the distance from the introduction pipe 222b to each of the ejection holes 222c increases. By increasing the diameter of each of the ejection holes 222c as described above, it is possible to set the pressure loss of the gas at the uppermost ejection hole 222c or the lowermost ejection hole 222c to be equal to that of an ejection hole provided between the uppermost ejection hole 222c or the lowermost ejection hole 222c.

Referring to FIG. 13A, two distributors 222 are provided. As described above, the pressure becomes different as the distance from the introduction pipe 222b increases. Therefore, according to the example shown in FIG. 13A, a distance between the introduction pipe 222b and a front end portion 222e of the distribution structure 222a is shortened. Further, the ejection holes 222c are provided in the direction of gravity. That is, it is configured to supply the gas to the housing 227 by using a plurality of distribution structures 222a.

With such a configuration, for example, it is possible to easily control the pressure loss as compared with other examples. Therefore, it is possible to more uniformly supply the gas to each of the substrates S.

Referring to FIG. 13B, a plurality of distributors (for example two distributors) 222 are arranged in parallel in the vertical direction. Further, a plurality of introduction pipes 222b are arranged at point-symmetric positions. In one distributor among the distributors 222, the introduction pipe 222b is connected below the lowermost ejection hole 222c, and in the other distributor among the distributors 222, the introduction pipe 222b is connected above the uppermost ejection hole 222c. That is, the plurality of introduction pipes 222b are configured to face a plurality of collision portions 222d, respectively.

In such a configuration, for example, when performing the film processing step S208, the gas may be simultaneously supplied through the two distributors 222. By simultaneously supplying the gas through the two distributors 222, it is possible to uniformize the degree of decomposition of the gas in the vertical direction.

Specifically, according to the configuration shown in FIG. 13B, the front end portion 222e where the degree of decomposition of the gas is high and a base portion 222f where the degree of decomposition of the gas is low are configured to be provided adjacent to each other. Therefore, it is possible to uniformize the degree of decomposition of the gas in the vertical direction at downstream sides of the two distributors 222. As a result, it is possible to uniformly process the substrates S.

Further, the configuration shown in FIG. 13B is advantageous in that a large amount of the gas can be supplied. As described above, when the degree of decomposition of the gas increases as the pressure increases, the gas is decomposed as it moves toward the front end of the distribution structure 222a since the pressure increases toward the front end of the distribution structure 222a. On the other hand, when a large amount of the gas is supplied to the distribution structure 222a at one time, the pressure at the front end portion 222e becomes high and the decomposition of the gas is promoted. As a result, it is difficult to supply the large amount of the gas with one nozzle. On the other hand, according to the configuration shown in FIG. 13B, since the two distributors 222 are provided, it is possible to supply a large amount of the gas without promoting the decomposition of the gas.

Although the configuration shown in FIG. 13B is described using the two distributors 222, the configuration shown in FIG. 13B is not limited thereto. For example, three or more distributors 222 may be provided. In such a case, as shown in FIG. 13C, different introduction pipes 222b are provided in the vertical direction. In such a configuration, the introduction pipe 222b of a first distributor among three distributors 222 is arranged at a lower portion of the distribution structure 222a of the first distributor, the introduction pipe 222b of a second distributor among the three distributors 222 is arranged at an upper portion of the distribution structure 222a of the second distributor, and the introduction pipe 222b of a third distributor among the three distributors 222 is arranged between the introduction pipe 222b of the first distributor and the introduction pipe 222b of the second distributor in the vertical direction. With such a configuration, it is possible to more uniformly process the substrates S. Further, it is also possible to supply a larger amount of the gas to each of the substrates S without promoting the decomposition of the gas.

### Other Embodiments of Present Disclosure

While the technique of the present disclosure is described in detail by way of the embodiments described above, the technique of the present disclosure is not limited thereto. The technique of the present disclosure may be modified in various ways without departing from the scope thereof.

For example, the embodiments described above are described by way of an example in which, in the film processing process performed by the substrate processing apparatus, the film is formed on the substrate S by using the first gas and the second gas. However, the technique of the present disclosure is not limited thereto. That is, as the process gases used in the film-forming process, other gases may be used to form different films. Further, the technique of the present disclosure may also be applied to film-forming processes using three or more different process gases as long as the three or more different process gases are non-simultaneously supplied (that is, supplied in a non-overlapping manner). Specifically, an element such as titanium (Ti), silicon (Si), zirconium (Zr) and hafnium (Hf) may be used as the first element. In addition, for example, an element such as nitrogen (N) and oxygen (O) may be used as the second element. Further, it is more preferable that silicon is used as the first element.

For example, the embodiments described above are described by way of an example in which the HCDS gas is used as the first gas. However, the technique of the present disclosure is not limited thereto. For example, a gas containing silicon and a Si—Si bond may be used as the first gas. That is, for example, a gas such as tetrachloro dimethyl disilane ((CH3)2Si2Cl4, abbreviated as TCDMDS) and dichloro tetramethyl disilane ((CH3)4Si2Cl2, abbreviated as DCTMDS) may be used as the first gas. As shown in FIG. 7B, the TCDMDS contains a Si—Si bond, and further contains a chloro group and an alkylene group. Further, as shown in FIG. 7C, the DCTMDS contains a Si—Si bond, and further contains a chloro group and an alkylene group.

For example, the embodiments described above are described by way of an example in which the film-forming process is performed by the substrate processing apparatus. However, the technique of the present disclosure is not limited thereto. That is, the technique of the present disclosure can be applied not only to the film-forming process of forming the film exemplified in the embodiments described above but also to other film-forming processes of forming another films. Further, one or more constituents of the above-described embodiments (and examples) may be substituted with one or more constituents of other embodiments (and other examples), or may be added to other embodiments (and other examples). Further, a part of one or more constituents of the above-described embodiments (and examples) may be omitted, or substituted with or added by other constituents.

According to some embodiments of the present disclosure, it is possible to provide the technique capable of forming the film of the high step coverage performance even with respect to the concave structure of the high aspect ratio.

What is claimed is:

1. A substrate processing apparatus comprising:
a substrate support configured to support a plurality of substrates;
a process chamber in which the substrate support is capable of being accommodated;
an upstream side gas guide comprising:
a housing connected to a side portion of the process chamber and extending in a direction away from the process chamber; and
a plurality of partition plates arranged in a vertical direction in the housing;
a distributor provided with a plurality of ejection holes arranged in the vertical direction such that a gas is capable of being supplied through the plurality of ejection holes between adjacent partition plates among the plurality of partition plates, between the housing and an uppermost partition plate among the plurality of partition plates or between the housing and a lowermost partition plate among the plurality of partition plates; and
a process chamber heater provided between the process chamber and the distributor such that a part thereof is located in vicinity of an adjacent portion of the housing.

2. The substrate processing apparatus of claim 1, wherein an inner pressure of the distributor is higher than an inner pressure of the upstream side gas guide.

3. The substrate processing apparatus of claim 2, wherein the inner pressure of the distributor is set to be a pressure at which a decomposition of the gas passing through an inner portion of the distributor is not promoted.

4. The substrate processing apparatus of claim 1, wherein a diameter of each of the plurality of ejection holes is smaller than a distance between the adjacent partition plates, a distance between the uppermost partition plate and the housing or a distance between the housing and the lowermost partition plate.

5. The substrate processing apparatus of claim 1, wherein the distributor comprises a source gas distributor through which a source gas is capable of being distributed and a reactive gas distributor through which a reactive gas is capable of being distributed.

6. The substrate processing apparatus of claim 5, wherein the source gas comprises a silicon-containing gas containing a silicon—silicon bond.

7. The substrate processing apparatus of claim 5, further comprising:
a plurality of source gas supply nozzles through which the source gas is supplied; and
a plurality of reactive gas supply nozzles through which the reactive gas is supplied,
wherein the plurality of source gas supply nozzles and the plurality of reactive gas supply nozzles are provided at the upstream side gas guide, and
wherein the source gas distributor and the plurality of source gas supply nozzles are connected such that a plurality of ejection holes of the source gas distributor are capable of being in communication with the plurality of source gas supply nozzles, respectively, and
wherein the reactive gas distributor and the plurality of reactive gas supply nozzles are connected such that a plurality of ejection holes of the reactive gas distributor are capable of being in communication with the plurality of reactive gas supply nozzles, respectively.

8. The substrate processing apparatus of claim 7, wherein a distance between each of the plurality of source gas supply nozzles and each of the plurality of partition plates provided therebelow is equal.

9. The substrate processing apparatus of claim 7, wherein the plurality of partition plates are provided in the vertical direction, and a combination of a source gas supply nozzle among the plurality of source gas supply nozzles and a reactive gas supply nozzle among the plurality of reactive gas supply nozzles is provided for each of the plurality of partition plates.

10. The substrate processing apparatus of claim 1, wherein the distributor is provided with:
a gas introduction pipe; and
a distribution structure connected to the gas introduction pipe, wherein the plurality of ejection holes are provided at the distribution structure, and
wherein a distance from the gas introduction pipe to an uppermost ejection hole among the plurality of ejection holes and a distance from the gas introduction pipe to a lowermost ejection hole among the plurality of ejection holes are set to be equal to each other.

11. The substrate processing apparatus of claim 1, further comprising
one or more distributors,
wherein each of the distributor and the one or more distributors is provided with a gas introduction pipe, and
wherein the gas introduction pipe of the distributor and the gas introduction pipes of the one or more distributors are arranged point-symmetrically.

12. The substrate processing apparatus of claim 1, further comprising
one or more distributors, and
wherein each of the distributor and the one or more distributors is provided with a gas introduction pipe, and
the gas introduction pipe of a first distributor among the distributor and the one or more distributors is connected to the first distributor below a lowermost ejection hole of the first distributor, and the gas introduction pipe of a second distributor among the distributor and the one or more distributors is connected to the second distributor above an uppermost ejection hole of the second distributor.

13. The substrate processing apparatus of claim 1, further comprising
one or more distributors, and
wherein the distributor and the one or more distributors are arranged in the vertical direction, the plurality of ejection holes of the distributor are arranged so as not to overlap with one another in the vertical direction and a plurality of ejection holes of each of the one or more distributors are arranged so as not to overlap with one another in the vertical direction.

14. The substrate processing apparatus of claim 1, further comprising:
a gas supply structure provided with the distributor and located adjacent to the housing; and
an upstream side heater provided around the gas supply structure and configured to heat the distributor to a temperature at which the gas supplied into the distributor is not re-liquefied.

15. The substrate processing apparatus of claim 14, further comprising
a metal cover provided between the gas supply structure and the upstream side heater,
wherein the upstream side heater is configured to heat the distributor via the metal cover.

16. The substrate processing apparatus of claim 14, wherein the upstream side heater is provided at least along an arrangement direction of the distributor.

17. The substrate processing apparatus of claim 1, further comprising:
a gas supply structure provided with the distributor and located adjacent to the housing;
an upstream side heater provided around a surface of the housing between the gas supply structure and the adjacent portion; and
a nozzle arranged parallel to the upstream side heater and provided in the upstream side gas guide.

18. The substrate processing apparatus of claim 1, further comprising:
a gas supply structure provided with the distributor and provided adjacent to the housing; and
an upstream side heater provided around a surface of the housing between the gas supply structure and the adjacent portion and around the gas supply structure,
wherein the upstream side heater is controlled to heat the distributor to a temperature at which the gas supplied into the distributor is not re-liquefied, and
wherein the process chamber heater is controlled to heat the process chamber to a temperature at which the gas supplied into the process chamber is capable of being decomposed.

19. A method of manufacturing a semiconductor device, comprising:
(a) accommodating a substrate support in a process chamber while a plurality of substrates are supported by the substrate support; and
(b) processing the plurality of substrates by supplying a gas to the process chamber through an upstream side gas guide and a distributor while heating the process chamber by a process chamber heater,
wherein the upstream side gas guide comprises:
a housing connected to a side portion of the process chamber and extending in a direction away from the process chamber; and
a plurality of partition plates arranged in a vertical direction in the housing, and
wherein the distributor is provided with a plurality of ejection holes arranged in the vertical direction such that the gas is capable of being supplied through the plurality of ejection holes between adjacent partition plates among the plurality of partition plates, between the housing and an uppermost partition plate among the plurality of partition plates or between the housing and a lowermost partition plate among the plurality of partition plates, and
wherein the process chamber heater is provided between the process chamber and the distributor such that a part thereof is located in vicinity of the housing.

20. A non-transitory computer-readable recording medium storing a program that causes, by a computer, a substrate processing apparatus to perform:
(a) accommodating a substrate support in a process chamber while a plurality of substrates are supported by the substrate support; and
(b) processing the plurality of substrates by supplying a gas to the process chamber through an upstream side gas guide and a distributor while heating the process chamber by a process chamber heater,
wherein the upstream side gas guide comprises:
a housing connected to a side portion of the process chamber and extending in a direction away from the process chamber; and
a plurality of partition plates arranged in a vertical direction in the housing, and wherein the distributor is provided with a plurality of ejection holes arranged in the vertical direction such that the gas is capable of being supplied through the plurality of ejection holes between adjacent partition plates among the plurality of partition plates, between the housing and an uppermost partition plate among the plurality of partition plates or between the housing and a lowermost partition plate among the plurality of partition plates, and
wherein the process chamber heater is provided between the process chamber and the distributor such that a part thereof is located in vicinity of the housing.
